(19) United States
(12) Patent Application Publication
(10) Pub. No.: US 2023/0102791 A1
(43) Pub. Date: Mar. 30, 2023

(54) APPARATUS FOR SUBSTRATE DICING AND METHOD THEROF

(71) Applicant: Samsung Electronics Co., Ltd., Suwon-si (KR)

(72) Inventors: Sung Ho JANG, Hwaseong-si (KR); Min Hwan SEO, Hwaseong-si (KR); Jang Hwi LEE, Hwaseong-si (KR); Young Chul KWON, Asan-si (KR); Sang Woo BAE, Seoul (KR); Akinori OKUBO, Hwaseong-si (KR); Jung Chul LEE, Hwaseong-si (KR); Won Don JOO, Incheon (KR)

(21) Appl. No.: 17/740,494

(22) Filed: May 10, 2022

(30) Foreign Application Priority Data
Sep. 29, 2021 (KR) 10-2021-0128921

(51) Int. Cl. B23K 26/53; B23K 26/38; B23K 26/03

(52) U.S. Cl. CPC B23K 26/53; B23K 26/38; B23K 26/032; B23K 2101/40

(57) ABSTRACT

A method for dicing a substrate includes setting a target height for forming a first reforming region inside a target substrate, the target height being a distance from an upper surface of the target substrate to the first reforming region; irradiating a laser beam to a first sample substrate including a first film and a second film being in contact with the first film, and setting a target condition on the basis of a sample condition that results in forming a condensing point of the laser beam on an upper surface of the first film being in contact with the second film; and irradiating the target substrate with the laser beam according to the target condition to form the first reforming region inside the target substrate, wherein a thickness of the second film is the target height.

This application claims priority under 35 U.S.C. § 119 to Korean Patent Application No. 10-2021-0128921 filed on Sep. 29, 2021 in the Korean Intellectual Property Office, the disclosure of which is incorporated herein by reference in its entirety.

### BACKGROUND

### 1. Field of the Disclosure

The present disclosure relates to a method for dicing a substrate and an apparatus for dicing the substrate.

### 2. Description of the Related Art

A semiconductor may be manufactured through various processes. For example, a semiconductor manufacturing process may include a procedure of cutting a wafer or the like. The wafer may be cut in a variety of ways. The wafer may be cut, using a blade. Alternatively, the wafer may be cut, using a laser. To cut the wafer using the laser, a stealth dicing method which condenses the laser beam inside the wafer may be used. Cracks may occur in a portion in which the laser beam is condensed inside the wafer. The wafer may be cut on the basis of the cracked portion.

### SUMMARY

Aspects of the present disclosure provide a method for dicing a substrate having improved accuracy.

Aspects of the present disclosure also provide an apparatus for substrate dicing having improved accuracy.

According to an aspect of the present disclosure, method for dicing a substrate includes setting a target height for forming a first reforming region inside a target substrate, the target height being a distance from an upper surface of the target substrate to the first reforming region; irradiating a laser beam to a first sample substrate including a first film and a second film being in contact with the first film, and setting a target condition on the basis of a sample condition that results in forming a condensing point of the laser beam on an upper surface of the first film being in contact with the second film; and irradiating the target substrate with the laser beam according to the target condition to form the first reforming region inside the target substrate, wherein a thickness of the second film is the target height.

According to an aspect of the present disclosure, a method for dicing a substrate includes irradiating a first sample substrate including a first film and a second film being in contact with the first film with a first laser beam; monitoring a second laser beam resulting from the first laser beam is reflected by an upper surface of the first film being in contact with the second film, and setting a target condition on the basis of a sample condition which results in forming a condensing point of the first laser beam on the upper surface of the first film; and forming a first reforming region inside a target substrate different from the first sample substrate according to the target condition, and dicing the target substrate.

According to an aspect of the present disclosure, an apparatus for dicing a substrate includes a laser generator which generates a laser beam; a stage onto which a first sample substrate including a first film having a reflectivity to the laser beam higher than an absorptivity to the laser beam, and a second film being in contact with the first film is loaded; an optical system which irradiates the first sample substrate with the laser beam; and a controller which monitors a laser beam in which the laser beam is reflected by an upper surface of the first film being in contact with the second film, and controls at least one of the stage and the optical system to set a target condition so that a condensing point of the laser beam is formed on the upper surface of the first film, wherein when the first sample substrate is unloaded from the stage and a target substrate including the same material as the second film is loaded, the controller controls the stage and the optical system according to the target condition to control a reforming region inside the target substrate.

However, aspects of the present disclosure are not restricted to the one set forth herein. The and other aspects of the present disclosure will become more apparent to one of ordinary skill in the art to which the present disclosure pertains by referencing the detailed description of the present disclosure given below.

### BRIEF DESCRIPTION OF THE DRAWINGS

These and other aspects and features of the present disclosure will become more apparent by describing in detail exemplary embodiments thereof referring to the attached drawings, in which:

FIG. 1 is a diagram for explaining an apparatus for dicing the substrate according to some embodiments;

FIG. 2 is a flowchart for explaining a method for dicing the substrate according to some embodiments;

FIG. 3 is a diagram for explaining the method for dicing the substrate according to FIG. 2;

FIG. 4 is a flowchart for explaining step S300 of FIG. 2;

FIG. 5 is a flowchart for explaining step S310 of FIG. 4;

FIGS. 6 and 7 are diagrams for explaining a method for dicing the substrate according to FIG. 5;

FIG. 8 is a diagram for explaining the apparatus for dicing the substrate according to some embodiments;

FIGS. 9 and 10 are diagrams for explaining a first sample substrate of FIG. 1;

FIGS. 11 and 12 are diagrams for explaining the first sample substrate of FIG. 1;

FIG. 13 is a diagram for explaining the apparatus for dicing the substrate according to some embodiments;

FIG. 14 is a flowchart for explaining S310 of FIG. 4;

FIG. 15 is a flowchart for explaining S310 of FIG. 4;

FIG. 16 is a diagram for explaining the operation of the apparatus for dicing the substrate according to some embodiments;

FIG. 17 is a diagram for explaining the method for dicing the substrate according to some embodiments;

FIG. 18 is a diagram for explaining the apparatus for dicing the substrate according to some embodiments;

FIG. 19 is a diagram for explaining the apparatus for dicing the substrate according to some embodiments;

FIG. 20 is a diagram for explaining the apparatus for dicing the substrate according to some embodiments; and

FIG. 21 is a diagram for explaining the apparatus for dicing the substrate according to some embodiments.

### DETAILED DESCRIPTION OF THE EMBODIMENTS

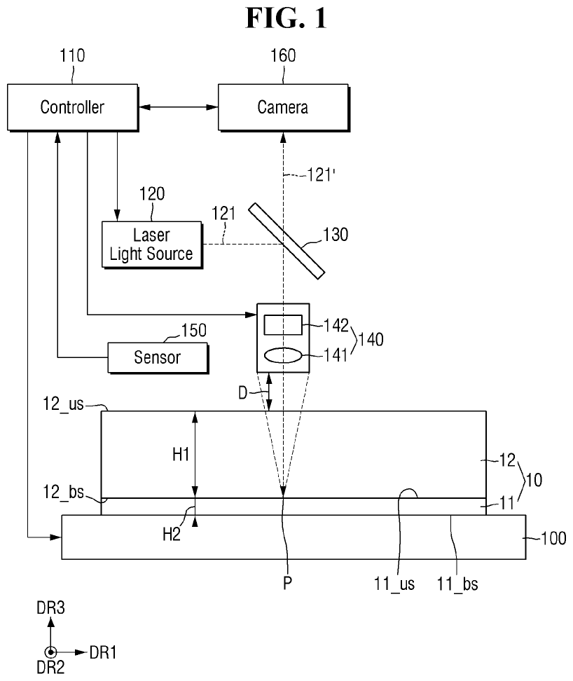

FIG. 1 is a diagram for explaining an apparatus for dicing a substrate according to some embodiments.

Referring to FIG. 1, the apparatus for dicing the substrate according to some embodiments may include a stage 100, a controller 110, a laser light source 120, a beam splitter 130, an optical system 140, a sensor 150, and a camera 160.

The first sample substrate 10 may be loaded onto the stage 100. The stage 100 may move in a third direction DR3 under the control of the controller 110. The stage 100 may move the first sample substrate 10 in the third direction DR3.

The stage 100 may move in a first direction DR1 and a second direction DR2 intersecting the first direction DR1 under the control of the controller 110. The second direction DR2 may be perpendicular to the first direction DR1, and the third direction DR3 may be perpendicular to the first direction DR1 and the second direction DR2.

The first sample substrate 10 may include a first film 11, and a second film 12 on the first film 11.

The first film 11 may include a lower surface 11_bs loaded onto the stage 100, and an upper surface 11_us opposite to the lower surface 11_bs.

The first film 11 may reflect at least a part of a first laser beam 121 provided from the laser light source 120. Reflectivity of the first film 11 to the first laser beam 121 provided from the laser light source 120 may be higher than, for example, absorptivity of the first film 11 to the beam 121 provided from the laser light source 120.

A thickness H2 of the first film 11 may be set depending on the reflectivity of the first film 11 according to the wavelength of the first laser beam 121 provided from the laser light source 120. A thickness H1 of the first film 11 may have a value that allows the camera 160 to image a first laser beam 121′ reflected by the upper surface 11_us of the first film 11.

The first film 11 may include or be formed of, for example, one of tin, chromium, platinum, gold, silver, aluminum, and tin.

The second film 12 may include a lower surface 12_bs that is in contact with the upper surface 11_us of the first film 11, and an upper surface 12_us opposite to the lower surface 12_bs. The lower surface 12_bs of the second film 12 may be placed on the same plane as the upper surface 11_us of the first film 11. The term “contact,” or “in contact with,” as used herein refers to a direct connection (i.e., touching), unless the context indicates otherwise.

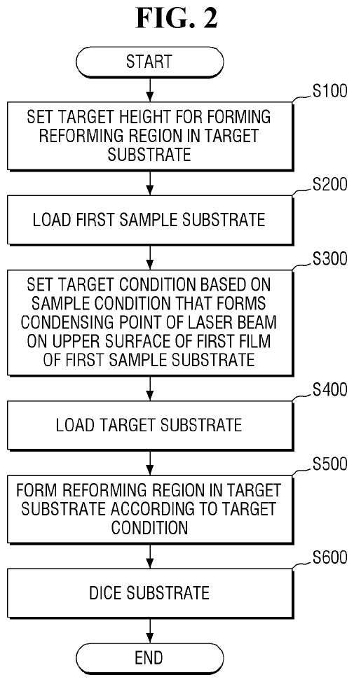

The thickness H1 of the second film 12 may be a target thickness to be described later. The second film 12 may include or be formed of the same material as a target substrate to be described later. The second film 12 may include or may be, for example, silicon. Hereinafter, description will be provided using FIG. 2.

The controller 110 may generally control the apparatus for dicing the substrate.

The laser light source 120 may provide the first laser beam 121. The laser light source 120 may adjust power according to the control of the controller 110. The laser light source 120 may provide the first laser beam 121 having a power smaller than power for generating a reforming region to the inside of the first sample substrate 10.

The beam splitter 130 may be placed between the optical system 140 and the camera 160. The beam splitter 130 may reflect a part of the first laser beam 121 provided from the laser light source 120 and provide it to the optical system 140. Further, the beam splitter 130 may allow a part of the first laser beam 121 provided from the laser light source 120 to penetrate. The beam splitter 130 may include, for example, a half mirror.

The optical system 140 may be placed between the first sample substrate 10 and the beam splitter 130. The optical system 140 may condense the first laser beam 121 on the first sample substrate 10. The optical system 140 may condense the first laser beam 121 on the upper surface 11_us of the first film 11. A condensing point P, also described as a focal point, of the first laser beam 121 may be formed on the upper surface 11_us of the first film 11, which may be at the lower surface 12_bs of the second film 12.

In some embodiments, the optical system 140 may include an objective lens 141 and a correction collar 142. At least a part of the first laser beam 121 may be reflected by the upper surface 11_us of the first film 11. The first laser beam 121′ reflected by the upper surface 11_us of the first film 11 may pass through the objective lens 141. The correction collar 142 may correct an aberration generated inside the first sample substrate 10. For example, the correction collar 142 may adjust a distance between a plurality of lenses constituting the objective lens 141 to correct the aberration generated inside the first sample substrate 10.

The sensor 150 may sense a distance D between the first sample substrate 10 and the optical system 140. The sensor 150 may sense whether the distance D between the first sample substrate 10 and the optical system 140 is equal to a distance provided from the controller 110. The sensor 150 may sense a relative magnitude of the distance D between the first sample substrate 10 and the optical system 140 and the distance provided from the controller 110. The sensor 150 may provide the sensed relative magnitude to the controller 110.

The camera 160 may be provided with the first laser beam 121′ which is reflected by the upper surface 11_us of the first film 11 and passes through the beam splitter 130. The camera 160 may sense the first laser beam 121′ and form an imaging data (also described as image data). The camera 160 may provide the imaging data to the controller 110.

The camera 160 may be, for example, a CCD (charge-coupled device) camera.

The controller 110 may determine whether the condensing point P of the first laser beam 121 is formed on the upper surface 11_us of the first film 11 on the basis of the imaging data. The controller 110 may adjust the distance D between the first sample substrate 10 and the optical system 140 or the correction collar 142 so that the condensing point P of the first laser beam 121 is formed on the upper surface 11_us of the first film 11, on the basis of the imaging data. Accordingly, the condensing point P of the first laser beam 121 may be formed on the upper surface 11_us of the first film 11. The controller 110 may set the distance D between the first sample substrate 10 and the optical system 140 and the value of the correction collar 142 (e.g., a value that corresponds to a distance between lenses of the correction collar 142) at this time as sample conditions.

The apparatus for dicing the substrate may further include a display unit. The display unit may be provided with the imaging data, the sample conditions, the target conditions, and the like provided from the controller 110. Further, the apparatus for dicing the substrate may further include an input unit. The controller 110 may control the apparatus for dicing the substrate according to the sample conditions, the target conditions, and the like provided from the input unit.

The controller 110 may set the target conditions for forming the reforming region on the target substrate on the basis of the aforementioned sample conditions. Hereinafter, description will be provided using FIG. 2.

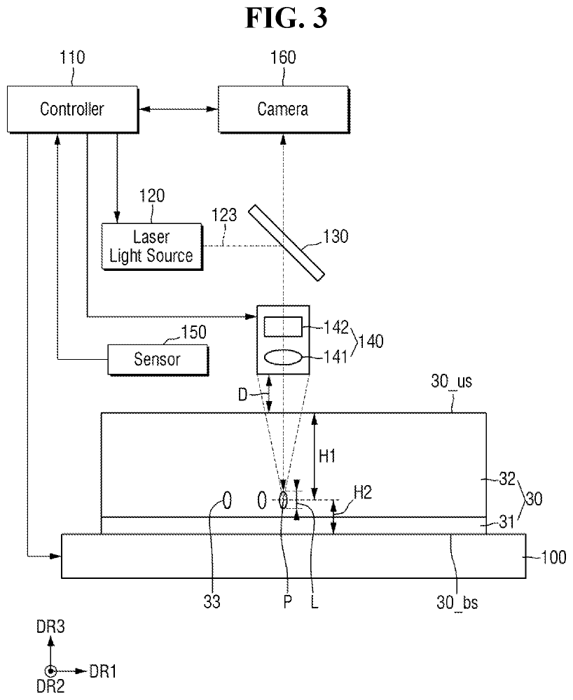

FIG. 2 is a flowchart for explaining a dicing method of the substrate according to some embodiments. FIG. 3 is a diagram for explaining the dicing method of the substrate according to

Referring to FIGS. 2 and 3, a target height H1 for later forming a reforming region 33 may be set inside the target substrate 30 (S100).

The target substrate 30 may include a circuit layer 31, and a wafer layer 32 on the circuit layer 31. The target substrate 30 may include a lower surface 30_bs loaded onto the stage 100, and an upper surface 30_us opposite to the lower surface 30_bs.

The circuit layer 31 may include transistors, wiring, and the like. The wafer layer 32 may include silicon.

The target height H1 may be a particular distance from the upper surface 30_us of the target substrate 30 to the reforming region 33 to be formed later. The target height H1 may be, for example, the distance from the upper surface 30_us of the target substrate 30 to a central portion of the reforming region 33 to be formed later. The target height H1 may be set so that the circuit layer 31 is not damaged due to the reforming region 33.

The reforming region 33 may be a portion in which a third laser beam 123 is irradiated into the target substrate 30 and cracks are generated. The reforming region 33 may have different physical characteristics from those of the target substrate 30. When the target substrate 30 includes silicon, the reforming region 33 may include amorphous silicon or polysilicon. Reforming region 33 may also be described herein as a transforming region or a transformed region, which may include material (e.g., silicon) that is to be transformed or that has been transformed by the laser beam.

Next, referring to FIGS. 1 and 2, the first sample substrate 10 may be loaded onto the stage 100 (S200). The first sample substrate 10 is the same as the first sample substrate 10 described using FIG. 1.

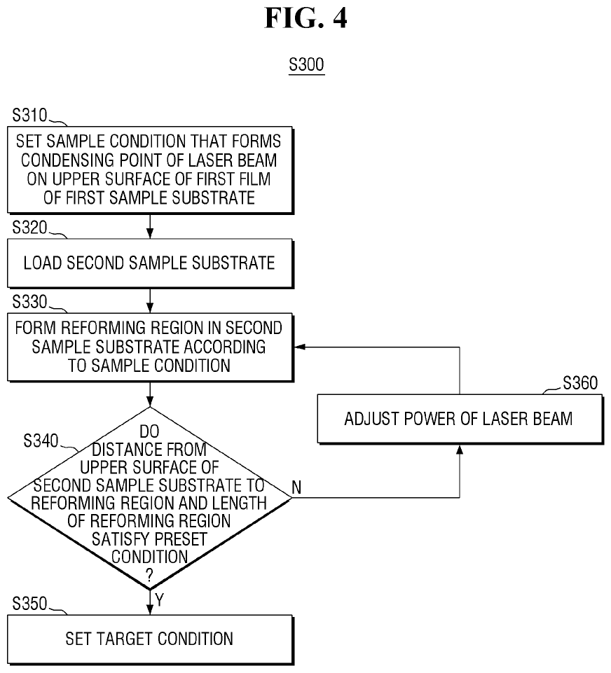

Subsequently, the target condition may be set on the basis of the sample condition for forming the condensing point P of the first laser beam 121 on the upper surface 11_us of the first film 11 of the first sample substrate 10 (S300). Hereinafter, description will be provided using FIG. 4.

In some embodiments, the sample condition may include at least one of a distance D between the first sample substrate 10 and the optical system 140 and a value of the correction collar 142. The first sample substrate 10 may then be unloaded from the stage 100.

Next, referring to FIGS. 2 and 3, the target substrate 30 may be loaded onto the stage 100

Subsequently, the reforming region 33 may be formed on the target substrate 30 according to the target conditions (S500).

Specifically, the controller 110 may provide the sensor 150 with the distance between the first sample substrate 10 and the optical system 140 included in the target conditions set in step S300. The sensor 150 may sense whether the distance D between the target substrate 30 and the optical system 140 is equal to the distance included in the target condition. For example, the sensor 150 may sense the relative magnitude of the distance D between the target substrate 30 and the optical system 140 and the distance included in the target condition. The sensor 150 may provide the relative magnitude to the controller 110.

In some embodiments, the controller 110 may control the stage 100 to move in the third direction DR3 on the basis of the relative magnitude provided from the sensor 150. The stage 100 may move so that the distance D between the target substrate 30 and the optical system 140 becomes the distance included in the target condition.

The laser light source 120 may provide the third laser beam 123. The laser light source 120 may provide the third laser beam 123 having power greater than that of the first laser beam 121 of FIG. 1 under the control of the controller 110. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The beam splitter 130 may reflect a part of the third laser beam 123 and provide it to the optical system 140. Further, the beam splitter 130 may allow a part of the third laser beam 123 to penetrate.

The controller 110 may control the optical system 140 to have a correction collar value included in the target condition. The optical system 140 may be set to have a correction collar value included in the target condition. Therefore, the condensing point P of the third laser beam 123 may be formed at a point having a target height H1 from the upper surface 30_us of the target substrate 30 inside the target substrate 30. As a result, the reforming region 33 may be formed inside the target substrate 30.

Subsequently, the target substrate 30 may be diced (S600).

Specifically, cracks may grow along the reforming region 33 to generate crack lines. After that, a part of the target substrate 30 may be ground. For example, an unnecessary portion may be cut from the upper surface 30_us of the target substrate 30. After that, the target substrate 30 may be expanded and diced. The target substrate 30 may receive a force, for example, in the first direction DR1 and the second direction DR2. The target substrate 30 may be diced along the crack lines and separated into a plurality of semiconductor chips.

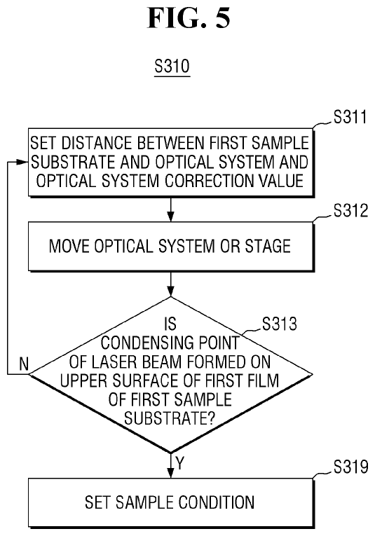

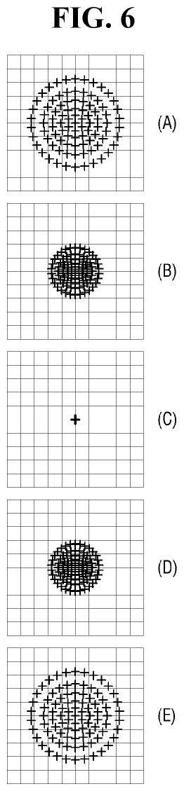

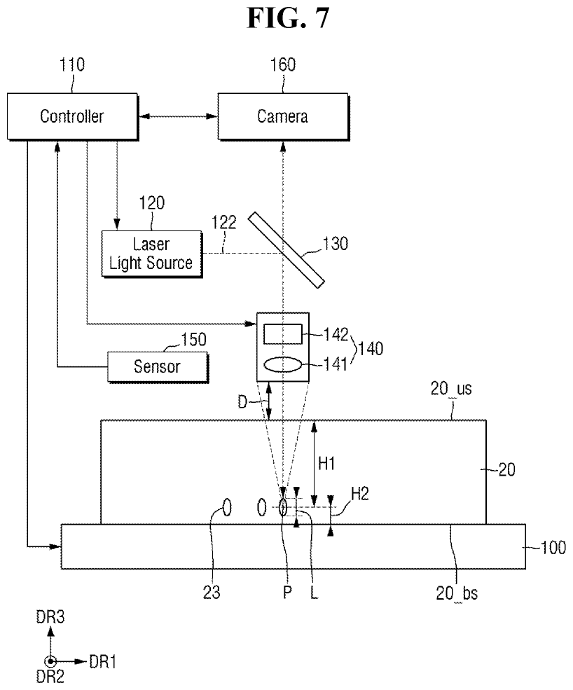

FIG. 4 is a flowchart for explaining the step S300 of FIG. 2. FIG. 5 is a flowchart for explaining the step of S310 of FIG. 4. FIGS. 6 and 7 are diagrams for explaining the dicing method of the substrate according to FIG. 5.

Referring to FIGS. 1 and 4, after the first sample substrate 10 is loaded onto the stage 100 (S200 of FIG. 2), the controller 110 may set the sample condition in which the condensing point P of the first laser beam 121 is formed on the upper surface 11_us of the first film 11 (S310).

Specifically, referring to FIG. 5, the controller 110 may set the distance D between the first sample substrate 10 and the optical system 140 and may set the value of the correction collar 142 (S311). This distance and value may be set for the purpose of causing the condensing point P of the first laser beam 121 to be formed on the upper surface 11_us of the first film 310.

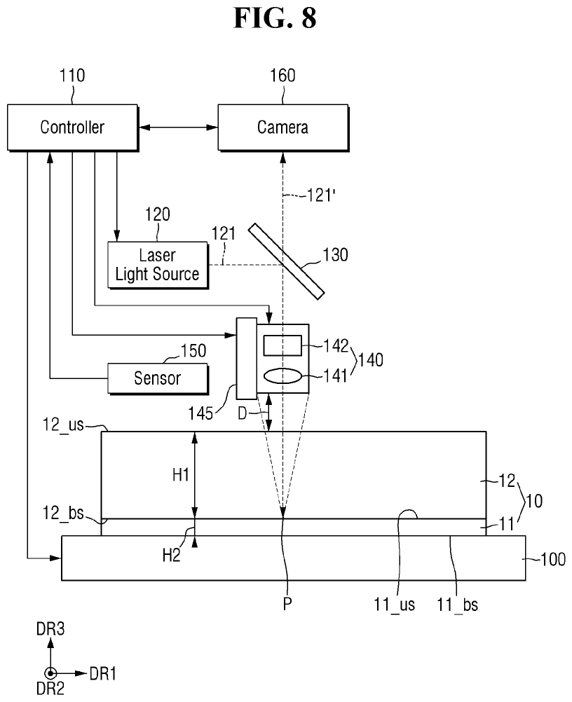

The optical system 140 or the stage 100 may move according to the control of the controller 110 (S312). For example, as shown in FIG. 1, the stage 100 may move in the third direction DR3. Alternatively, as shown in FIG. 8 which will be described later, the optical system 140 may move in the third direction DR3 by a drive unit 145.

Subsequently, the controller 110 may determine whether the condensing point P of the first laser beam 121 is formed on the upper surface 11_us of the first film 11 of the first sample substrate 10 (S313). For example, due to certain conditions, even though the distance D between the first sample substrate 10 and the optical system 140, and the value of the correction collar 142 may be set to cause the condensing point P of the first laser beam 121 to be formed on the upper surface 11_us of the first film 310, this may not precisely happen.

The camera 160 may sense the first laser beam 121′ reflected by the upper surface 11_us of the first film 11 to form imaging data. The controller 110 may determine whether the condensing point P of the first laser beam 121 is formed on the upper surface 11_us of the first film 11 of the first sample substrate 10, on the basis of the imaging data.

When the condensing point P of the first laser beam 121 is formed on the upper surface 11_us of the first film 11 in step S313, the controller 110 may set the distance D between the first sample substrate 10 and the optical system 140 and the value of the correction collar 142 set in step S311, as sample conditions (S319).

If the condensing point P of the first laser beam 121 is not formed on the upper surface 11_us of the first film 11 in step S313, the process returns to step S311, and the controller 110 may adjust the distance D between the first sample substrate 10 and the optical system 140, and the value of the correction collar 142.

FIG. 6 is an example of imaging data imaged by the camera 160 according to the distance D between the first sample substrate 10 and the optical system 140. FIGS. 6(A), 6(B), 6(D), and 6(E) are imaging data when the condensing point P is not formed on the lower surface 12_bs of the second film 12 (e.g., upper surface 11_us of the first film 11), and FIG. 6(C) is an imaging data when the focusing point P is formed on the lower surface 12_bs of the second film 12 (e.g., upper surface 11_us of the first film 11). The controller 110 may adjust the distance D between the first sample substrate 10 and the optical system 140 and/or the value of the correction collar 142 on the basis of the imaging data. The controller 110 may set the sample condition in which the condensing point P of the first laser beam 121 is formed on the upper surface 11_us of the first film 11 on the basis of the imaging data. These adjustments and the setting, and the other steps described herein, can be performed automatically in some embodiments, based on computer program code configured to perform these tasks (e.g., by evaluating the image for the proper clarity or size, and sending instructions to adjust the locations of the optical system 140 and the lenses of the correction collar 142 based on the evaluation). The computer program code may be stored on a computer-readable medium on the controller 110 or in another hardware device of the apparatus for dicing a substrate of the various embodiments. Controller 110 may be part of a system that includes, for example, a computer including memory storage, one or more microprocessors, and other known components configured to perform the various analysis, calculation, and control steps disclosed herein.

The distance D between the first sample substrate 10 and the optical system 140 value and/or the value of the correction collar 142 included in the sample conditions may have a specific value. Alternatively, the distance D between the first sample substrate 10 and the optical system 140 and/or the value of the correction collar 142 included in the sample conditions may have a specific range. The first sample substrate 10 may then be unloaded from the stage 100.

Next, referring to FIGS. 4 and 7, the second sample substrate 20 may be loaded onto the stage 100 (S320).

The second sample substrate 20 may include a lower surface 20_bs loaded onto the stage 100, and an upper surface 20_us opposite to the lower surface 20_bs. The second sample substrate 20 may include the same materials as the second film 12 of the first sample substrate 10 and the wafer layer 32 of the target substrate 30. The second sample substrate 20 may include, for example, silicon.

Subsequently, the reforming region 23 may be formed inside the second sample substrate 20 according to the sample conditions (S330).

Specifically, the controller 110 may provide the sensor 150 with the distance between the first sample substrate 10 and the optical system 140 included in the sample conditions set in step S310. The sensor 150 may sense whether the distance D between the second sample substrate 20 and the optical system 140 is equal to the distance included in the sample condition. For example, the sensor 150 may sense the relative magnitude of the distance between the second sample substrate 20 and the optical system 140 and the distance D included in the sample conditions. The sensor 150 may provide the relative magnitude to the controller 110. The controller 110 may control the stage 100 to move in the third direction DR3 on the basis of the relative magnitude provided from the sensor 150. The stage 100 may be driven so that the distance D between the second sample substrate 20 and the optical system 140 becomes the distance included in the sample conditions.

The laser light source 120 may provide the second laser beam 122. The laser light source 120 may provide the second laser beam 122 having power greater than that of the first laser beam 121 of FIG. 1 under the control of the controller 110.

The beam splitter 130 may reflect a part of the second laser beam 122 and provide it to the optical system 140. Further, the beam splitter 130 may allow a part of the second laser beam 122 to penetrate.

The controller 110 may control the optical system 140 to have the correction collar value included in the sample conditions. The optical system 140 may be set to have the correction collar value included in the sample conditions. Therefore, the condensing point P of the second laser beam 122 may be formed at a point having a target height H1 from the upper surface of the second sample substrate 20. The reforming region 23 may be formed at a point having the target height H1 from the upper surface 20_us of the second sample substrate 20 inside the second sample substrate 20.

Subsequently, the controller 110 may determine whether the distance from the upper surface 20_us of the second sample substrate 20 to the reforming region 23 and the length L of the reforming region 23 satisfy the preset conditions (S340).

Specifically, the camera 160 may image a cross section of the second sample substrate 20 (e.g., from a plan view or DR3 direction). The controller 110 may determine whether the distance D from the upper surface of the second sample substrate 20 to the central portion of the reforming region 23 (in the DR3 direction) and the length L of the reforming region 23 (in the DR3 direction) satisfy the preset conditions, on the basis of the imaging data.

The preset conditions may be a specific value or a specific range. The preset conditions about the distance D from the upper surface of the second sample substrate 20 to the central portion of the reforming region 23 (e.g., a center in the vertical direction) may be the target height H1 or a specific range centered on the target height H1.

Subsequently, when the distance D from the upper surface of the second sample substrate 20 to the central portion of the reforming region 23 and the length L of the reforming region 23 satisfy the preset conditions in step S340, the controller 110 may set the sample condition as the target condition (S350).

In some embodiments, the target condition may include or may be at least one of the power of the laser beam, the distance D between the first sample substrate 10 and the optical system 140, and the value of the correction collar 142.

When the distance from the upper surface of the second sample substrate 20 to the central portion of the reforming region 23 and the length L of the reforming region 23 do not satisfy the preset conditions in the step S340, the controller 110 may adjust power of the second laser beam 122 (S360). For example, when the distance from the upper surface of the second sample substrate 20 to the reforming region 23 and the length L of the reforming region 23 are smaller than the preset conditions, the controller 110 may increase the power of the second laser beam 122. When the distance from the upper surface of the second sample substrate 20 to the reforming region 23 and the length L of the reforming region 23 are greater than the preset conditions, the controller 110 may decrease power of the second laser beam 122. Step S330 may then be performed again. In some embodiments, step S330 may be performed again on the same second sample substrate (e.g., on a different portion of the sample substrate). In some embodiments, the step S330 may be performed again on a third sample substrate different from the second sample substrate.

Since the method for dicing the substrate according to some embodiments checks the condensing point P of the laser beam on the basis of the laser beam reflected by the upper surface 11_us of the first film 11, the focus of the condensing point P of the laser beam can be more easily and accurately checked. Therefore, focus of the condensing point P of the laser beam can be checked, even without a step of actually forming and dicing the reforming region on the sample substrate. As a result, it is possible to reduce the time for actually forming the reforming region on the sample substrate, reduce the loss of the apparatus for dicing the substrate, reduce the loss of the sample substrate, and the like.

Further, the method for dicing the substrate according to some embodiments may set the sample condition and the target condition to directly form the condensing point P of the laser beam on the lower surface 12_bs of the second film 12, using the second film 12 having the target height H2 and including the same material as the target substrate 30. Therefore, the condensing point P of the laser beam may be formed more accurately and quickly at the target height H2 in the target substrate 30, as compared with a case where the sample condition and the target condition are set on the basis of the refractive index and the thickness of the target substrate 30. Also, since the sample conditions are set more accurately, the time for finding the target conditions may be shortened. It should be noted that the substrates in FIGS. 1, 3, and 7 are not drawn to scale. That is, the thickness of the circuit later 31 in FIG. 1 maybe exaggerated for the purpose of explanation, and the distance H2 shown in FIG. 1 may be the same distance H2 shown in FIGS. 3 and 7.

FIG. 8 is a diagram for explaining the apparatus for dicing the substrate according to some embodiments.

Referring to FIG. 8, the apparatus for dicing the substrate according to some embodiments may further include a drive unit 145. The drive unit 145 may move in the third direction DR3 according to the control of the controller 110. The drive unit 145 may move the optical system 140 in the third direction DR3.

In some embodiments, the controller 110 may control the stage 100 and/or the drive unit 145 to move in the third direction DR3 on the basis of the relative magnitude provided from the sensor 150. The controller 110 may control the stage 100 and/or the drive unit 145 according to the sample condition or the target condition.

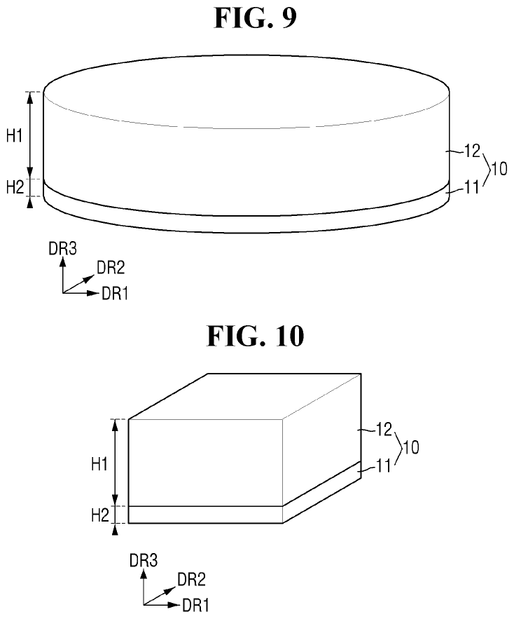

FIGS. 9 and 10 are diagrams for explaining examples of the first sample substrate of FIG. 1.

Referring to FIG. 9, in some embodiments, the first sample substrate 10 may have a wafer shape. The first film 11 may be, for example, a wafer (e.g., a circular wafer) that is etched to have a target height H1. The second film 12 may be formed, for example, on the lower surface 11_bs of the first film 11 by a vapor deposition process.

In some embodiments, the upper surface of the first sample substrate 10, that is, the upper surface 12_us of the second film 12, may be flat. The first sample substrate 10 may be in a state in which no patterning is performed.

Referring to FIG. 10, in some embodiments, the first sample substrate 10 may be a cut wafer. For example, the first sample substrate 10 may have a rectangular parallelepiped shape. The shape of the first sample substrate 10 is not limited thereto, and may be various. The shape of the first sample substrate 10 may have any shape including the first film 11 and the second film 12.

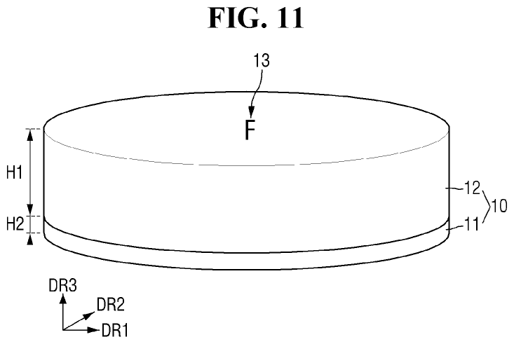

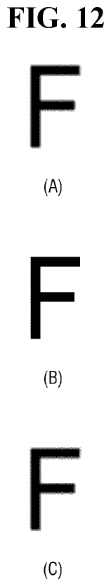

FIGS. 11 and 12 are diagrams for explaining the first sample substrate of FIG. 1.

Referring to FIGS. 1 and 11, in some embodiments, the upper surface of the first sample substrate 10, that is, the upper surface 12_us of the second film 12, may include a patterned portion 13.

The patterned portion 13 may, for example, protrude from the upper surface 12_us of the second film 12. Alternatively, the patterned portion 13 may be recessed from the upper surface 12_us of the second film 12. Alternatively, the patterned portion 13 may have a top surface coplanar with the upper surface of the first sample substrate 10.

The camera 160 may image the patterned portion 13, and the controller 110 may set the sample conditions on the basis of the imaged data provided from the camera 160.

FIG. 12 is an example of imaging data imaged by the camera 160 according to the distance D between the first sample substrate 10 and the optical system 140. FIGS. 12(A) and 12(C) are imaging data when the condensing point P is not formed on the lower surface 12_bs of the second film 12, and FIG. 12(B) is an imaging data when the condensing point P is formed on the lower surface 12_bs of the second film 12. The controller 110 may adjust the distance D between the first sample substrate 10 and the optical system 140 and/or the value of the correction collar 142 on the basis of the imaging data. The controller 110 may set the sample conditions in which the condensing point P of the first laser beam 121 is formed on the upper surface 11_us of the first film 11, for example, on the basis of sharpness of the patterned portion 13.

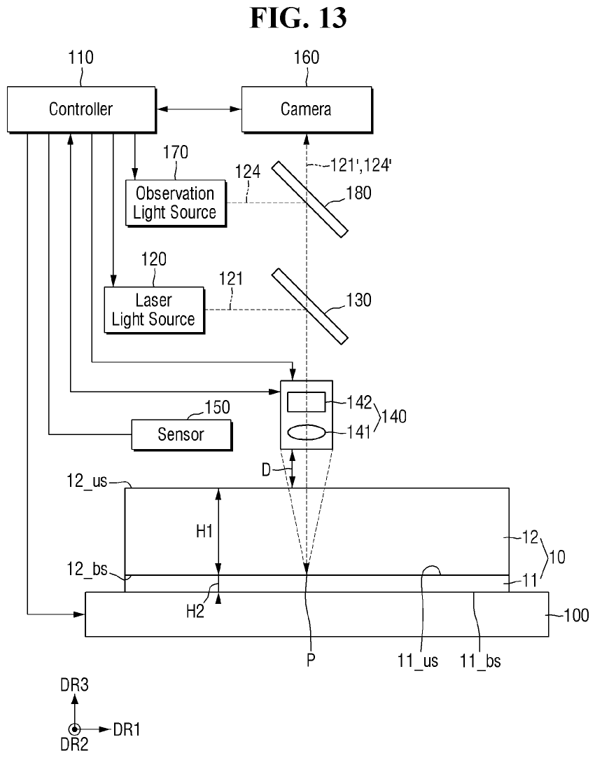

FIG. 13 is a diagram for explaining the apparatus for dicing the substrate according to some embodiments. For convenience of explanation, points different from those of FIG. 1 will be mainly described.

Referring to FIG. 13, the apparatus for dicing the substrate according to some embodiments may further include an observation light source 170 and a beam splitter 180.

The observation light source 170 may provide a light source 124 for lighting the upper surface of the first sample substrate 10. The light source 124 may be, for example, visible rays.

The beam splitter 180 may reflect a part of the light source 124 and provide it to the first sample substrate 10. The light source 124 may light the upper surface of the first sample substrate 10. Referring to FIG. 12, the first sample substrate 10 may include a patterned portion 13.

The camera 160 may be provided with a light source 124′ that is reflected by the upper surface 11_us of the first film 11 and passes through the beam splitter 130. The camera 160 may sense the light source 124′ to form imaging data obtained by imaging the upper surface 11_us of the first film 11. As a result, the camera 160 may provide imaging data obtained by more clearly imaging the shape of the patterned portion 13.

Alternatively, the observation light source 170 may be placed on the optical system 140 to provide the light source 124 to the first sample substrate 10 without the beam splitter 180. Further, another camera that senses the light source 124′ reflected by the first sample substrate 10 may be further included.

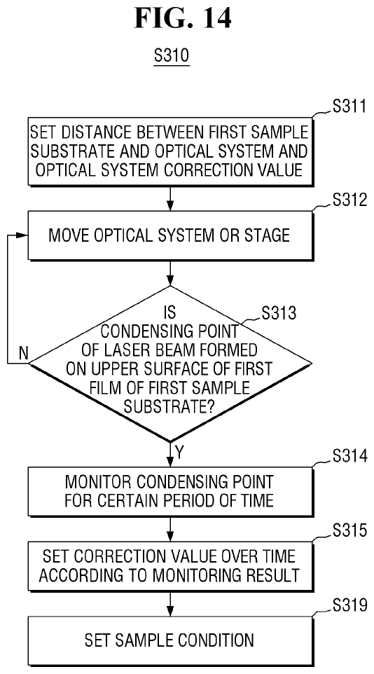

FIG. 14 is a flowchart for explaining step S310 of FIG. 4. For convenience of explanation, points different from those described referring to FIG. 5 will be mainly described.

Referring to FIGS. 1 and 14, when the condensing point P of the first laser beam 121 is formed on the upper surface 11_us of the first film 11 in the step S313, the controller 110 may monitor the condensing point P of the first laser beam 121 for a certain period of time (S314). The camera 160 may sense the first laser beam 121′ reflected by the first film 11 for a certain period of time to generate imaging data, and provide this to the controller 110.

Subsequently, the controller 110 may set a correction value over time according to the monitoring result (S315). For example, the controller 110 may monitor shaking or the like of the first laser beam 121′ on the basis of the imaging data provided for a certain period of time. The controller 110 may calculate the correction value of the first laser beam 121′ over time according to the monitoring result.

Subsequently, the controller 110 may set the sample condition in consideration of the correction value over time. Therefore, the method for dicing the substrate according to some embodiments may set more accurate target conditions.

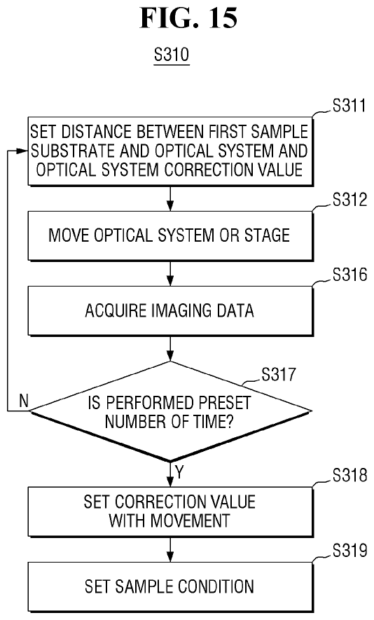

FIG. 15 is a flowchart for explaining step S310 of FIG. 4. For convenience of explanation, points different from those described referring to FIG. 5 will be mainly described.

Referring to FIGS. 1 and 15, after the optical system 140 or the stage 100 has moved under the control of the controller 110, the controller 110 may acquire the imaging data of the first laser beam 121′ reflected by the upper surface 11_us of the first film 11 (S316). The imaging data may be provided from the camera 160.

The controller 110 may determine whether the steps S312 and S316 have been performed a preset number of times (S317).

In step S317, when steps S312 and S316 are performed a preset number of times, the controller 110 may set a correction value with the movement (S318). When the distance D between the first sample substrate 10 and the optical system 140 and the value of the correction collar 142 is the same, the controller 110 may monitor the change of the first laser beam 121′ with the movement of the optical system 140 or the stage 100. That is, the controller 110 repeatedly acquires the imaging data, and may distinguish the motion of the first laser beam 121′ with the movement of the optical system 140 or the stage 100, and the motion of the first laser beam 121′ with the change in the distance D and the value of the correction collar 142. The controller 110 may calculate a correction value with the movement according to the monitoring result.

Subsequently, the controller 110 may set the sample condition in consideration of the correction value according to the correction. Therefore, the method for dicing the substrate according to some embodiments may correct the error with the motion of the apparatus for dicing the substrate and set more accurate target conditions.

If steps S312 and S316 are not performed a preset number of times in step S317, the process returns to step S312 and the controller 110 may move the optical system 140 or the stage 100 again.

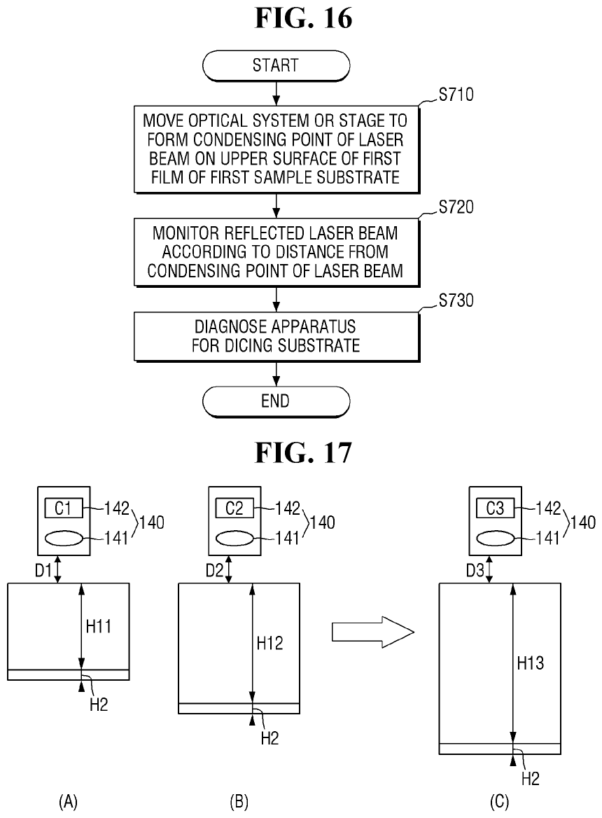

FIG. 16 is a diagram for explaining the operation of the apparatus for dicing the substrate according to some embodiments.

Referring to FIGS. 1 and 16, the optical system 140 or the stage 100 may move to form the condensing point P of the first laser beam 121 on the upper surface 11_us of the first film 11 of the first sample substrate 10 (S710). The step S710 may be the same as step S310 described using FIG. 5.

The controller 110 may monitor the first laser beam 121′ reflected according to the distance from the condensing point P of the first laser beam 121 (S720). The controller 110 may move the optical system 140 or the stage 100 in the state of the step S710 to change the distance D between the first sample substrate 10 and the optical system 140. The camera 160 may generate the imaging data by sensing the first laser beam 121′ reflected by the first sample substrate 10 for each changed distance D.

The controller 110 may diagnose whether the apparatus for dicing the substrate is normal according to the monitoring result (S730). The controller 110 may monitor the first laser beam 121′ corresponding to the distance D between the first sample substrate 10 and the optical system 140 to diagnose whether the apparatus for dicing the substrate is normal (e.g., within a set of predetermined parameters). Further, the controller 110 may determine the type of aberration generated in the apparatus for dicing the substrate on the basis of the imaging data. For example, the controller 110 may diagnose the apparatus for dicing the substrate is normal when the relationship of the first laser beam 121′ corresponding to distance D between the first sample substrate 10 and the optical system 140 satisfies a predetermined relationship. For example, the controller 110 may determine the type of aberration generated in the apparatus for dicing the substrate based on the relationship of the first laser beam 121′ corresponding to distance D between the first sample substrate 10 and the optical system 140. For example, aberration may include a monochromatic aberration and a chromatic aberration. The chromatic aberration results from the dispersion characteristics of a medium of a lens, and the monochromatic aberration results from the geometrical shape of a lens or a mirror irrespective of dispersion and may include a spherical aberration, a comatic aberration, an astigmatism, a curvature aberration, and a distortion aberration. An aberration correction refers to an operation of restoring an original image by correcting a portion distorted by an aberration in an observed image.

FIG. 17 is a diagram for explaining the method for dicing the substrate according to some embodiments.

FIGS. 17(A) to 17(C) each show sample conditions when the target heights are the first height H11 to the third height H13, as described using FIG. 5. When the target height is the first height H11, the distance between the first sample substrate and the optical system 140 may be D1, and value of the correction collar 142 (e.g., distances between and locations of various lenses) of the optical system 140 may be C1. When the target height is the second height H12, the distance between the first sample substrate and the optical system 140 may be D2, and the value of correction collar 142 of the optical system 140 may be C2. When the target height is the third height H13, the distance between the first sample substrate and the optical system 140 may be D3, and the value of the correction collar 142 of the optical system 140 may be C3.

Referring to FIGS. 1 and 17, the controller 110 may analyze a relationship between the sample conditions according to the target height on the basis of the sample conditions in the cases of (A) and (B). For example, the distance between the first sample substrate and the optical system 140 and/or the value of the correction collar 142 may be proportional depending on the target height. For example, the target height may have a linear relationship that can be used to form a linear chart comparing the target height to different sample conditions, such as different distances between the first sample substrate and the optical system 140, different correction collar values, etc.

The controller 110 may set the sample conditions when the target height is changed on the basis of the result of analyzing the relationship of the sample conditions according to the target height. For example, the controller 110 may calculate and set the sample condition in the case of (C) on the basis of the result of the analysis.

Alternatively, FIGS. 17(A) to 17(C) may each show target conditions when the target heights are the first height H11 to the third height H13, as described using FIG. 2. The controller 110 may analyze the relationship between the target conditions according to the target height, and may calculate and set the target conditions in the case of (C) on the basis of the analysis.

Therefore, the method for dicing the substrate according to some embodiments may set the target condition more quickly and easily even if the target height changes.

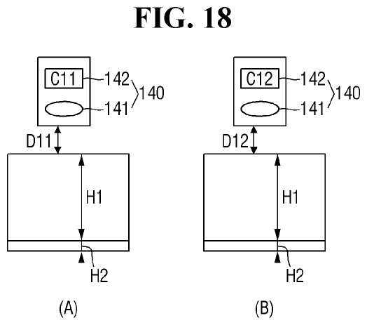

FIG. 18 is a diagram for explaining the apparatus for dicing the substrate according to some embodiments.

Referring to FIG. 18, when the target height is the first height H1, the distance between the first sample substrate and the optical system 140 included in the sample condition or the target condition in the first apparatus for dicing the substrate A is D11, the value of the correction collar 142 of the optical system 140 is C11.

When the target height is the first height H1, the distance between the first sample substrate and the optical system 140 included in the sample condition or the target condition in the second apparatus for dicing the substrate B is D12, and the value of the correction collar 142 of the optical system 140 is C12.

D11 and D12 may be the same as or different from each other. C11 and C12 may be the same as or different from each other. That is, even if the target height is the same as H1, the sample condition and the target condition may be different for each of the first apparatus for dicing the substrate A and the second apparatus for dicing the substrate B. In the method for manufacturing the apparatus for dicing the substrate according to some embodiments, since sample conditions and target conditions are set using the second film having the target height on the first film, it is possible to more quickly and easily set the sample conditions and the target conditions for each apparatus for dicing the substrate. Therefore, the sample condition and the target condition may be set for each dicing apparatus of the substrate, and the reforming region may be formed more accurately at a desired height inside the target substrate.

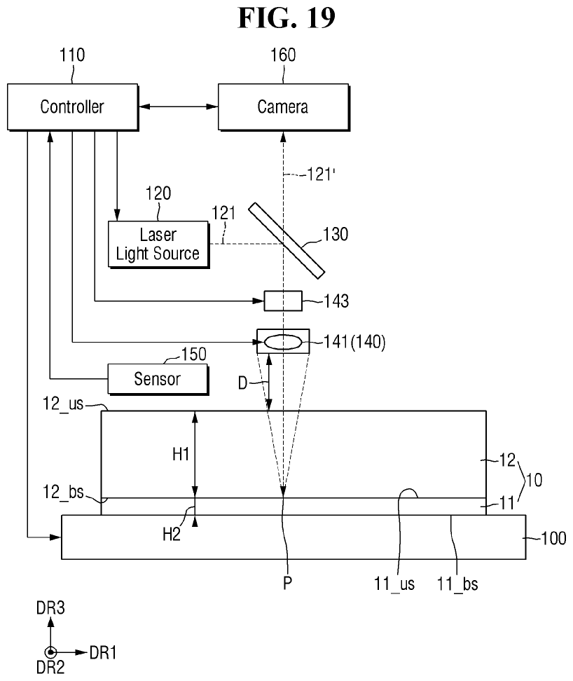

FIG. 19 is a diagram for explaining the apparatus for dicing the substrate according to some embodiments. For convenience of explanation, points different from those described referring to FIG. 1 will be mainly described.

Referring to FIG. 19, the apparatus for dicing the substrate according to some embodiments may include an optical system 140 including an objective lens 141, and a beam expander 143.

The beam expander 143 may be placed between the laser light source 120 and the optical system 140. For example, the beam expander 143 may be placed between the beam splitter 130 and the optical system 140. The beam expander 143 may be provided with the first laser beam 121 from the beam splitter 130. Alternatively, the beam expander 143 may be placed between the laser light source 120 and the beam splitter 130.

The optical system 140 may condense the first laser beam 121 provided from the beam expander 143 on the first sample substrate 10.

The controller 110 may adjust the distance D between the first sample substrate 10 and the optical system 140 or the beam expander 143 on the basis of the imaging data, so that the condensing point P of the first laser beam 121 is formed on the upper surface 11_us of the first film 11. Accordingly, the condensing point P of the first laser beam 121 may be formed on the upper surface 11_us of the first film 11. The controller 110 may set the distance D between the first sample substrate 10 and the optical system 140 and the set values of the beam expander 143 at this time as sample conditions (step S310 of FIG. 4).

The controller 110 may set the target conditions for forming the reforming region on the target substrate on the basis of the sample conditions (S350 of FIG. 4).

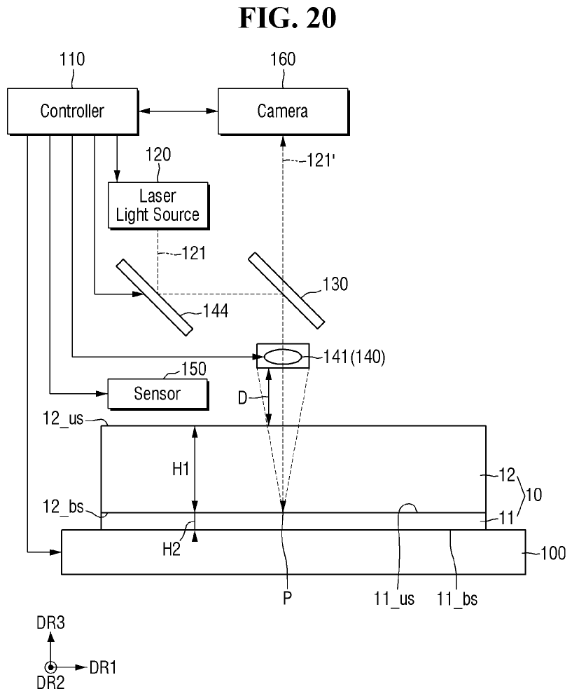

FIG. 20 is a diagram for explaining the apparatus for dicing the substrate according to some embodiments. For convenience of explanation, points different from those described referring to FIG. 1 will be mainly described.

Referring to FIG. 20, the substrate dicing apparatus according to some embodiments may include an optical system 140 including an objective lens 141, and a spatial light modulator 144.

The spatial light modulator 144 may be placed between the laser light source 120 and the optical system 140. For example, the spatial light modulator 144 may be placed between the laser light source 120 and the beam splitter 130. The spatial light modulator 144 may be provided with the first laser beam 121 from the laser light source 120.

In some embodiments, the spatial light modulator 144 may be a reflective spatial light modulator. The spatial light modulator 144 may reflect the first laser beam 121. The spatial light modulator 144 may adjust a reflection angle of the first laser beam 121. For example, the spatial light modulator 144 may include an LCoS (liquid crystal on silicon) panel, an LCD (liquid crystal display) panel, a DLP (digital light projection) panel, and the like.

The optical system 140 may condense the first laser beam 121, which is provided from the spatial light modulator 144, on the first sample substrate 10.

The controller 110 may adjust the distance D between the first sample substrate 10 and the optical system 140 or the spatial light modulator 144 on the basis of the imaging data, so that the condensing point P of the first laser beam 121 is formed on the upper surface 11_us of the first film 11. Accordingly, the condensing point P of the first laser beam 121 may be formed on the upper surface 11_us of the first film 11. The controller 110 may set the distance D between the first sample substrate 10 and the optical system 140 and the set values of the spatial light modulator 144 at this time as sample conditions (step S310 of FIG. 4). The set values of the spatial light modulator 144 may include the reflection angle of the first laser beam 121 (that is, an angle at which the spatial light modulator 144 is tilted).

The controller 110 may set the target conditions for forming the reforming region on the target substrate on the basis of the sample conditions (step S350 of FIG. 4).

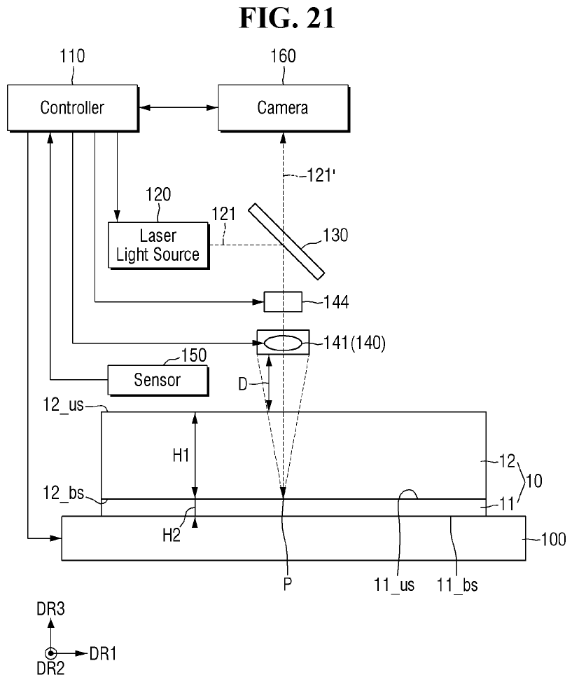

FIG. 21 is a diagram for explaining the apparatus for dicing the substrate according to some embodiments. For convenience of explanation, points different from those described referring to FIG. 20 will be mainly described.

Referring to FIG. 21, in the apparatus for dicing the substrate according to some embodiments, the spatial light modulator 144 may be placed between the beam splitter 130 and the optical system 140. The spatial light modulator 144 may be provided with the first laser beam 121 from the beam splitter 130. In some embodiments, the spatial light modulator 144 may be a transmissive spatial light modulator. The spatial light modulator 144 may modulate the first laser beam 121.

The optical system 140 may condense the first laser beam 121, which is provided from the spatial light modulator 144, on the first sample substrate 10.

The controller 110 may adjust the distance D between the first sample substrate 10 and the optical system 140 or the spatial light modulator 144 on the basis of the imaging data, so that the condensing point P of the first laser beam 121 is formed on the upper surface 11_us of the first film 11. Accordingly, the condensing point P of the first laser beam 121 may be formed on the upper surface 11_us of the first film 11. The controller 110 may set the distance D between the first sample substrate 10 and the optical system 140 and the set values of the spatial light modulator 144 at this time as sample conditions (S310 of FIG. 4). The set values of the spatial light modulator 144 may include the degree of modulation of the first laser beam 121.

The controller 110 may set the target conditions for forming the reforming region on the target substrate on the basis of the sample conditions (step S350 of FIG. 4).

According to the various above methods and apparatuses for dicing a wafer, one or more semiconductor chips formed form a wafer may be manufactured. For example, the target substrate 30 depicted in FIG. 3 may be a semiconductor substrate including one or more integrated circuits formed thereon. Each semiconductor circuit may form a memory device or a logic device. The semiconductor circuits may be separated to form individual semiconductor chips, using a laser beam of a dicing apparatus that is calibrated for power and for condensing point location based on the above description. One or more of the semiconductor chips may be disposed on a substrate, such as a package substrate, and covered with a molding layer or encapsulant to form semiconductor package.

In concluding the detailed description, those skilled in the art will appreciate that many variations and modifications may be made to the preferred embodiments without substantially departing from the principles of the present disclosure. Therefore, the disclosed embodiments of the disclosure are used in a generic and descriptive sense only and not for purposes of limitation.

1. A method for dicing a substrate comprising:
setting a target height for forming a first reforming region inside a target substrate, the target height being a distance from an upper surface of the target substrate to the first reforming region;
irradiating a laser beam to a first sample substrate including a first film and a second film being in contact with the first film, and setting a target condition on the basis of a sample condition that results in forming a condensing point of the laser beam on an upper surface of the first film being in contact with the second film; and
irradiating the target substrate with the laser beam according to the target condition to form the first reforming region inside the target substrate,
wherein a thickness of the second film is the target height.

2. The method for dicing the substrate of claim 1, wherein the target substrate includes the same material as the second film.

3. The method for dicing the substrate of claim 1, wherein a reflectivity of the first film to the laser beam is greater than an absorptivity of the first film to the laser beam.

4-7. (canceled)

8. The method for dicing the substrate of claim 1, further comprising:
setting the sample condition, wherein:
the setting of the sample condition includes:
at least one of setting of a first distance between the first sample substrate and an optical system for irradiating the first sample substrate with the laser beam, and setting of a correction collar value of the optical system.

9. The method for dicing the substrate of claim 8, wherein the setting of the target condition further includes:
irradiating a second sample substrate with the laser beam to form a second reforming region inside the second sample substrate according to the sample condition,
acquiring an imaging data of the second reforming region, and
adjusting the sample condition and setting the target condition on the basis of the imaging data.

10. The method for dicing the substrate of claim 9, wherein adjusting the sample condition and setting the target condition on the basis of the imaging data further includes:
acquiring a second distance between the second sample substrate and the optical system and a length of the second reforming region, on the basis of the imaging data, and
adjusting power of the laser beam on the basis of the second distance and the length of the second reforming region.

11. (canceled)

12. The method for dicing the substrate of claim 1, wherein the laser beam is a first laser beam, and the setting of the sample condition includes:
monitoring a second laser beam resulting from the first laser beam irradiated to the first sample substrate being reflected by the upper surface of the first film to set the sample condition.

13. The method for dicing the substrate of claim 12, wherein the setting of the sample condition includes:
repeatedly setting a first distance between the first sample substrate and an optical system that irradiates the first sample substrate with the first laser beam, moving at least one of the first sample substrate and the optical system according to the set first distance, and then, acquiring an imaging data obtained by imaging a second laser beam resulting from the laser beam irradiated to the first sample substrate being reflected by the upper surface of the first film, and
setting a correction value according to movement on the basis of the repeatedly imaged imaging data.

14. The method for dicing the substrate of claim 1, wherein the setting of the sample condition further includes:
monitoring a second laser beam resulting from the laser beam irradiated to the first sample substrate for a certain period of time being reflected by the upper surface of the first film to set a correction value over time.

15. The method for dicing the substrate of claim 1, wherein the setting of the sample condition further includes:
monitoring motion of the condensing point of the laser beam irradiated to the first sample substrate according to the distance between the first sample substrate and an optical system that irradiates the first sample substrate with the laser beam, and determining a type of aberration.

16. A method for dicing a substrate comprising:
irradiating a first sample substrate including a first film and a second film being in contact with the first film with a first laser beam;
monitoring a second laser beam resulting from the first laser beam being reflected by an upper surface of the first film being in contact with the second film, and setting a target condition on the basis of a sample condition which results in forming a condensing point of the first laser beam on the upper surface of the first film; and
forming a first reforming region inside a target substrate different from the first sample substrate according to the target condition, and dicing the target substrate.

17. The method for dicing the substrate of claim 16, wherein the first film includes one of tin, chromium, platinum, gold, silver, and aluminum.

18. The method for dicing the substrate of claim 16, wherein:
the first film includes a material different from the second film, and
the second film includes the same material as the target substrate.

19. The method for dicing the substrate of claim 16, wherein a distance from an upper surface of the target substrate to the first reforming region is a thickness of the second film.

20-24. (canceled)

25. An apparatus for dicing a substrate, comprising:
a laser generator configured to generate a laser beam;
a stage configured to support a first sample substrate including a first film having a reflectivity to the laser beam higher than an absorptivity to the laser beam, and a second film being in contact with the first film loaded thereon;
an optical system configured to irradiate the first sample substrate with the laser beam; and
a controller configured to:
monitor a laser beam reflected by an upper surface of the first film being in contact with the second film, and control at least one of the stage and the optical system to set a target condition so that a condensing point of the laser beam is formed on the upper surface of the first film, and
when the first sample substrate is unloaded from the stage and a target substrate including the same material as the second film is loaded, control the stage and the optical system according to the target condition to control a reforming region inside the target substrate.

26. The apparatus for dicing the substrate of claim 25, wherein an upper surface of the second film is flat.

27. The apparatus for dicing the substrate of claim 25, wherein the upper surface of the second film includes at least one of a convex portion and a concave portion from the upper surface of the second film.

28. The apparatus for dicing the substrate of claim 25, further comprising:
an observation light source configured to provide light to the upper surface of the second film; and
a camera configured to image the upper surface of the second film to generate imaging data,
wherein the controller is configured to set the target condition on the basis of the imaging data.

29. The apparatus for dicing the substrate of claim 25, wherein the first film includes one of tin, chromium, platinum, gold, silver, and aluminum.

30. The apparatus for dicing the substrate of claim 25, wherein a distance from the upper surface of the target substrate to the reforming region is a thickness of the second film.
